(19) United States
(12) Patent Application Publication
(10) Pub. No.: US 2014/0298648 A1
(43) Pub. Date: Oct. 9, 2014

(54) ELECTRONIC COMPONENT-EMBEDDED PRINTED CIRCUIT BOARD AND METHOD OF MANUFACTURING THE SAME

(71) Applicant: SAMSUNG ELECTRO-MECHANICS CO., LTD., Gyeonggi-Do (KR)

(72) Inventors: Hong Won KIM, Gyeonggi-Do (KR); Tae Sung JEONG, Gyeonggi-Do (KR)

(73) Assignee: SAMSUNG ELECTRO-MECHANICS CO., LTD., Gyeonggi-Do (KR)

(21) Appl. No.: 14/308,898

(22) Filed: Jun. 19, 2014

Related U.S. Application Data
(62) Division of application No. 12/692,413, filed on Jan. 22, 2010.

(30) Foreign Application Priority Data
Dec. 1, 2009 (KR) 10-2009-0117807

(51) Int. Cl. H05K 3/30

(52) U.S. Cl. CPC H05K 3/306
USPC 29/837

(57) ABSTRACT

Embodiments of the invention provide a method of manufacturing an electronic component-embedded printed circuit board. The method includes the steps of providing a base plate, which has a cavity formed in a thickness direction thereof and to one side of which tape is adhered, and disposing an electronic component in the cavity, such that an active surface of the electronic component is flush with one side of the base plate. The method further includes forming an insulating material layer on the other side of the base plate to bury the electronic component, and removing the tape from the one side of the base plate and then forming a first circuit layer including connection patterns coming into contact with connecting terminals of the electronic component on the one side of the base plate.

### CROSS REFERENCE TO RELATED APPLICATION

This application is a divisional application of U.S. patent application Ser. No. 12/692,413, entitled “ELECTRONIC COMPONENT-EMBEDDED PRINTED CIRCUIT BOARD,” filed on Jan. 22, 2010, and claims the benefit of and priority under 35 U.S.C. §119 to Korean Patent Application No. KR 10-2009-0117807, entitled “A PRINTED CIRCUIT BOARD COMPRISING EMBEDDED ELECTRONIC COMPONENT WITHIN AND A METHOD FOR MANUFACTURING THE SAME,” filed on Dec. 1, 2009, which are hereby incorporated by reference in their entirety into this application.

### BACKGROUND

1. Field of the Invention

The present invention relates to an electronic component-embedded printed circuit board and a method of manufacturing the same.

2. Description of the Related Art

Various technologies are required to realize a printed circuit board in a market which requires semiconductor packages having decreased profiles and a variety of functions.

For example, in the manufacturing of a flip chip ball grid array (FCBGA) package, the electro-conductive terminals or lands of ICs are directly soldered to the lands corresponding to the die bonding region on the surface of a substrate using re-flowable solder bumps or balls. In this case, electronic components are functionally connected to other elements of an electronic system through electro-conductive channels including substrate traces, and the substrate traces generally serve to transport signals transmitted between electronic components such as ICs and the like. In the case of FCBGA, ICs located at the upper end of a substrate and capacitors located at the lower end thereof are surface-mounted, respectively. In this case, the length of a circuit path for connecting the IC with the capacitor, that is, a connection circuit, is increased by the thickness of the substrate, so that impedance is increased, thereby deteriorating electrical performance. Further, since a part of the lower end of the substrate must be used to mount chips, design flexibility is limited, for example, users desiring to mount a ball array over the entire surface of the lower end thereof will be left unsatisfied.

In order to solve the above problems, electronic component packaging technologies for shortening the circuit path by embedding electronic components in a substrate are becoming, popular. Since electronic component-embedded printed circuit boards (PCBs) are provided in the organic substrate thereof with active/passive electronic components mounted on a conventional substrate in the form of package, a kind of next-generation three dimensional packaging technology, which can satisfy the multi-functionality attributable to the insurance of a residual surface area, the low loss of high frequency/high efficiency attributable to the minimization of signal transfer lines, and the miniaturization of the printed circuit board, can be developed, and a novel highly-functional packaging trend can be induced.

FIGS. 1A to 1E are sectional views sequentially showing a conventional method of manufacturing an electronic component-embedded printed circuit board. Hereinafter, conventional problems will be described with reference to FIGS. 1A to 1E.

First, as shown in FIG. 1A, there is provided a substrate 10 including: an insulation layer 3 having a cavity 2 in which an electronic component 1 is disposed and first circuit patterns 11 formed on both sides thereof; and a tape 4 adhered to one side of the insulation. layer 3.

Subsequently, as shown in FIG. 1B, the electronic component 1 is disposed in the cavity 2 of the insulation layer 3. In this case, the electronic component 1 is installed in the cavity 2 in a face-up manner using a vacuum adsorption header (not shown), and is supported by the tape 4.

Subsequently, as shown in FIG. 1C, an insulating material layer 5 is formed on the substrate 10 including the cavity 2. The insulating material layer 5 is formed in the cavity 2 provided therein with the electronic component 1, and thus the electronic component 1 is buried in the insulating material layer 5.

Subsequently, as shown in FIG. 1E, the tape 4 is removed from the substrate 10. Since the tape 4 serves to support the electronic component 1 before the electronic component is fixed in the substrate 10 by the insulating material layer 5, it is removed after the insulating material layer 5 is formed.

Subsequently, as shown in FIG. 1E, an insulating material layer 5 is formed even on the one side of the insulation layer 3 from which the tape 4 was removed, so that the electronic component 1 can be embedded in the substrate 10, and then circuit layers 8 including vias 6 and second circuit patterns 7 are formed on both sides of the insulating material layer 5. In this case, the vias 6 are electrically connected with the connecting terminals 9 of the electronic component 1.

Here, when via holes are formed in the insulating material layer 5 using a laser process in order to expose the connecting terminals 9, there is a problem in that it costs a lot. Further, there is a problem in that the electronic component 1 is perforated by a laser drill at the time of forming the via holes. Further, there is a problem in that the number of I/O pads and pitch of electronic components 1 which can be embedded in the substrate 10 are limited because the connecting terminals 9 of the electronic component 1 are connected with a circuit of the substrate 10 through the via holes formed using a laser drill.

Further, in this conventional method, since the first circuit patterns 11 must be provided on both sides of the insulation layer 3 and the second circuit patterns 7 must also be provided on both sides of the insulating material layer 5, there is a problem in that a printed circuit board cannot but be fabricated in a four or more layered structure, and thus design flexibility is limited.

Furthermore, the above-mentioned conventional method is problematic in that it is difficult to precisely dispose the electronic component 1 in the cavity 2, and in that it is difficult to match the vias 6 with the connecting terminals of the electronic component 1 because the connecting terminals 9 cannot be easily distinguished from the outside of the substrate 10.

### SUMMARY

Accordingly, embodiments of the invention have been made to solve the above-mentioned problems, and therefore provide an electronic component-embedded printed circuit board, which does not need additional via holes to be formed because the active surface of an electronic component is disposed such that it is flush with one side of a base plate, and which can improve the flexibility of circuit design, because the connecting terminals of an electronic component can be directly connected with the connection patterns of a first circuit layer without vias, and a method of manufacturing the same.

An embodiment of the invention provides an electronic component-embedded printed circuit board, including a base plate having a cavity formed therein in a thickness direction thereof, an electronic component which is disposed in the cavity such that an active surface of the electronic component is flush with one side of the base plate, an insulating material layer, which is formed on the other side of the base plate to bury the electronic component, and a first circuit layer which is formed on one side of the base plate and includes connection patterns coming into contact with connecting terminals of the electronic component.

According to an embodiment, the electronic component-embedded printed circuit board further includes a second circuit layer formed on an outer side of the insulating material layer.

According to an embodiment, the electronic component-embedded printed circuit board further includes vias penetrating the base plate and the insulating material layer and connecting the first circuit layer with the second circuit layer.

According to an embodiment, the electronic component-embedded printed circuit board further includes a buildup layer formed on one side of the base plate or an outer side of the insulating material layer.

According to an embodiment, the base plate is formed of an unclad CCL or an epoxy resin.

According to an embodiment, the base plate includes patterned copper foil formed on one side thereof such that the patterned copper foil corresponds to the first circuit layer.

According to an embodiment, the insulation material layer is formed of resin coated copper foil (RCC) or prepreg.

According to an embodiment, the active surface of the electronic component is an exposed surface of the connecting terminals of the electronic component.

According to an embodiment, the active surface of the electronic component is an exposed surface of a passivation layer, and the connecting terminals of the electronic component is buried in the passivation layer.

According to another embodiment of the invention, there is provided a method of manufacturing an electronic component-embedded printed circuit board, including providing a base plate, which has a cavity formed in a thickness direction thereof and to one side of which tape is adhered, disposing an electronic component in the cavity such that an active surface of the electronic component is flush with one side of the base plate, forming an insulating material layer on the other side of the base plate to bury the electronic component, and removing the tape from the one side of the base plate and then forming a first circuit layer including connection patterns coming into contact with connecting terminals of the electronic component on the one side of the base plate.

According to an embodiment, in forming the first circuit layer, a second circuit layer is formed on an outer side of the insulating material layer.

According to an embodiment, vias penetrating the base plate and the insulating material layer are formed such that the first circuit layer is connected with the second circuit layer.

According to an embodiment, the method of manufacturing an electronic component-embedded printed circuit board further includes forming a buildup layer on one side of the base plate or an outer side of the insulating material layer after the forming of the first circuit layer.

According to an embodiment, in disposing the electronic component, the active surface of the electronic component is an exposed surface of the connecting terminals of the electronic component.

According to an embodiment, in disposing the electronic component, the active surface of the electronic component is an exposed surface of a passivation layer, and the connecting terminals of the electronic component are buried in the passivation layer.

According to an embodiment, in providing the base plate, the tape is a polyimide (PI) tape, a thermofoaming tape or a UV tape.

According to an embodiment, in providing the base plate, the tape is provided with a supporting plate on one side thereof.

According to an embodiment, in providing the base plate, the base plate is formed of an unclad CCL or an epoxy resin.

According to an embodiment, in providing the base plate, the base plate is an insulating plate coated with copper foil on one side thereof, and, in forming the first circuit layer, the first circuit layer is formed by forming a plating layer on the copper foil of the base plate and then patterning the plating layer together with the copper foil of the base plate.

According to an embodiment in forming the insulating material layer, the insulation material layer is formed of resin coated copper foil or prepreg.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIGS. 1A to 1E are sectional views sequentially showing a conventional method of manufacturing an electronic component-embedded printed circuit board.

FIGS. 2 and 3 are sectional views showing electronic component-embedded printed circuit boards according to an embodiment of the invention.

FIGS. 4A, 4B, 5A, 5B, 6A, 6B to 10 are sectional views sequentially showing a method of manufacturing an electronic component-embedded printed circuit board according to an embodiment of the invention.

FIGS. 11 and 12 are sectional views showing electronic components according to an embodiment of the invention.

FIGS. 13 and 14 are sectional views showing electronic component-embedded printed circuit boards according to another embodiment of the invention.

FIGS. 15A, 15B, 16A, 16B, 17A, 17B to 22 are sectional views sequentially showing a method of manufacturing an electronic component-embedded printed circuit board according to another embodiment of the invention.

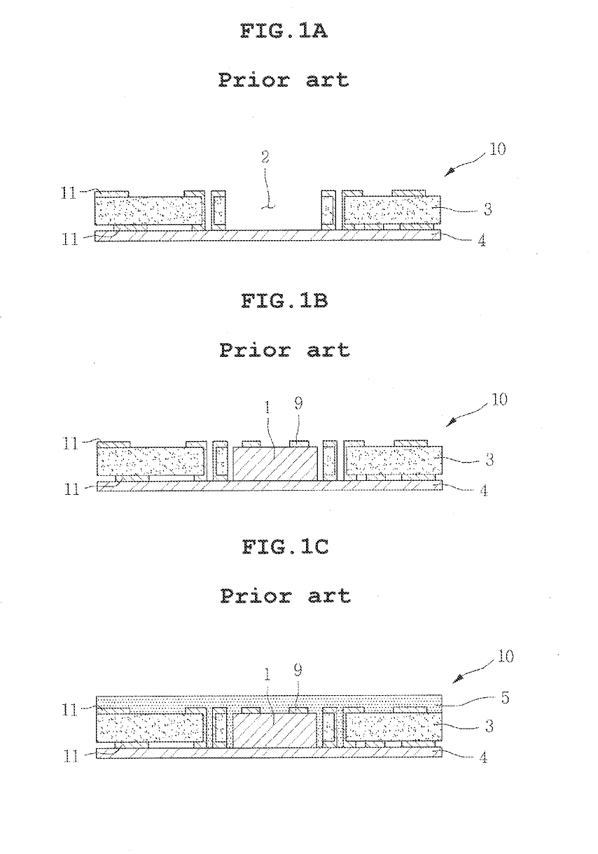

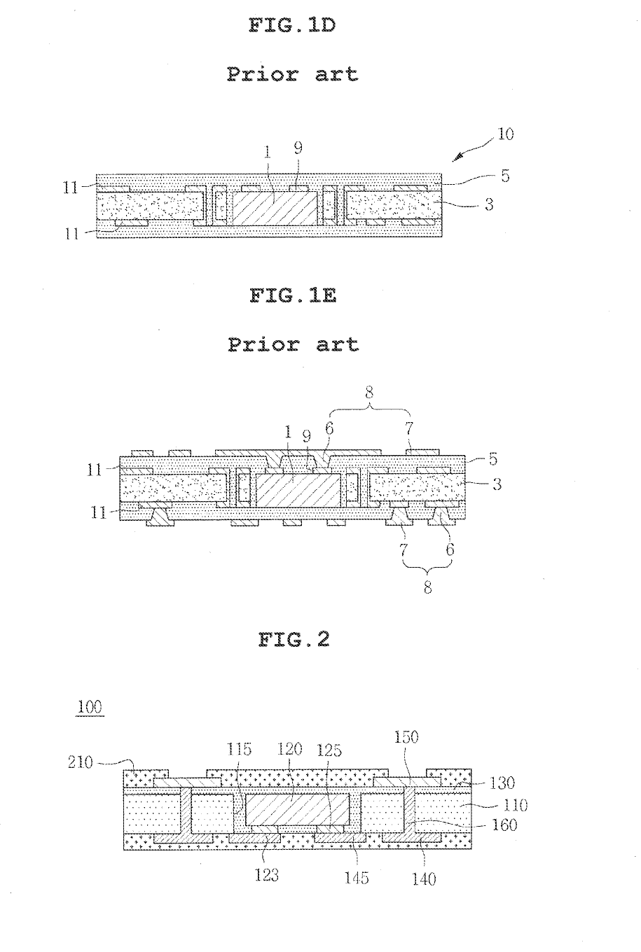

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

FIGS. 2 and 3 are sectional views showing electronic component-embedded printed circuit boards according to an embodiment of the invention.

As shown in FIG, 2, an electronic component-embedded printed circuit board 100, according to an embodiment of the invention, includes a base plate 110 having a cavity 115 formed in the thickness direction thereof, an electronic component 120, which is disposed in the cavity 115 such that the active surface of the electronic component 120 is flush with one side of the base plate 110, an insulating material layer, which is formed on the other side of the base plate 100 to bury the electronic component 120, and a first circuit layer 140, which is formed on the one side of the base plate 110 and includes connection patterns 145 coming into contact with connecting terminals 125 of the electronic component 120. Further, as shown in FIG. 3, the electronic component-embedded printed circuit board 200, according to this embodiment, further includes a buildup layer 170 formed on one side of the base plate 110 or the outer side of the insulating material layer 130.

According to an embodiment, the base plate 110 is made of an insulating material generally used to manufacture printed circuit boards. For example, the base plate 110 is formed using an unclad CCL, which is formed by removing copper foil from a CCL, or an epoxy resin. Further, a cavity 115, in which an electronic component 120 is to be installed, is formed in the base plate 110 in the thickness direction thereof.

According to an embodiment, the electronic component, which is electrically connected with a printed circuit board to perform specific functions, is an active element, such as a semiconductor element, or a passive element, such as a capacitor. Here, the active surface 123 of the electronic component 120 is flush with one side of the base plate 110, and thus the connecting terminals 125 can be directly connected to connection patterns 145 by plating the connecting terminals 125 with the connection patterns 145 without funning via holes. However, here, the fact that the active surface 123 of the electronic component 120 is flush with one side of the base plate 110 does not mean that the active surface 123 of the electronic component 120 is completely flush with one side of the base plate 110 mathematically, but means that slight tolerance attributable to the machining error occurring in a manufacturing process may be allowed.

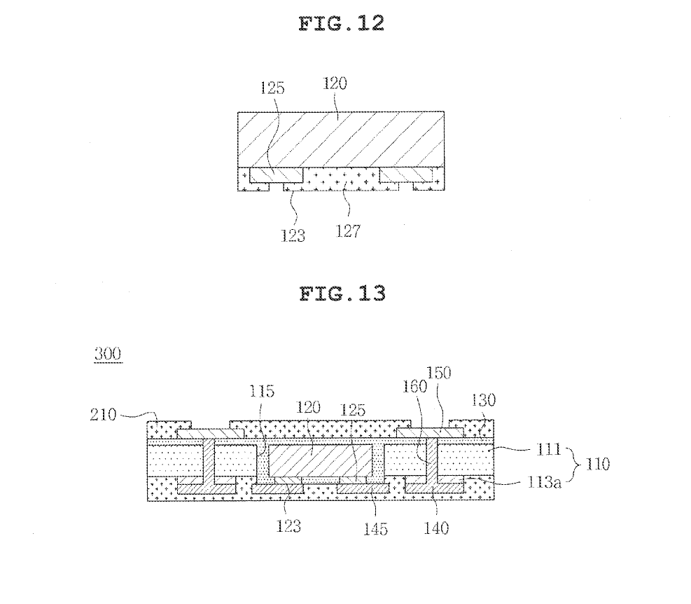

Meanwhile, the active surface 123 of the electronic component 120 means an outermost surface provided with the connecting terminals 125. Specifically, as shown in FIG. 11, when the connecting terminals 125 are formed to protrude, the active surface of the electronic component 120 is an exposed surface of the connecting terminals 125. In this embodiment, the active surface 123 of the electronic component 120 is explained with reference to the electronic component 120 shown in FIG. 11, but is not limited thereto. As shown in FIG. 12, when the connecting terminals 125 are buried in a passivation layer 127, the active surface of the electronic component 120 is an exposed surface of the passivation layer 127.

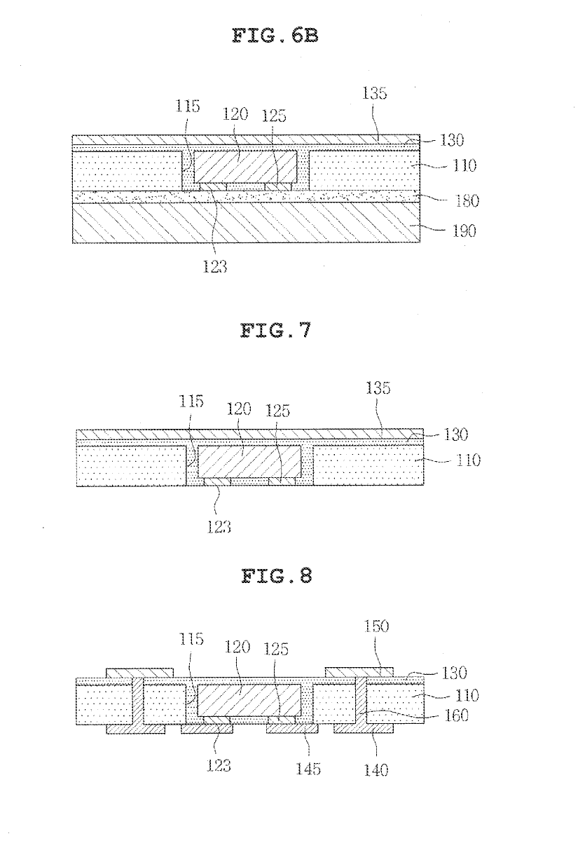

According to an embodiment, the insulating material layer 130, which serves to bury the electronic component 120, is formed on one side of the base plate and is charged in the cavity 115 provided therein with the electronic component 120. The insulating material layer is made of an insulating material generally used to manufacture printed circuit boards, for example, RCC or prepreg. When the insulating material layer is formed of RCC, the opposite surface of copper foil 135 (refer to FIGS. 6 and 7) of RCC is brought into contact with the base plate 110, and the copper foil 135 of RCC is patterned into a second circuit layer 150.

According to an embodiment, the first circuit layer 140 is formed on one side of the base plate 110, and is connected with the connecting terminals 125 of the electronic component 120 through the connection patterns 145 thereof. Since the active surface 123 of the electronic component 120 is flush with one side of the base plate 110, differently from conventional methods, vias are not additionally required, thus improving the reliability of connection, and, a laser process is omitted, thus decreasing the manufacturing cost of a printed circuit board. Meanwhile, the first circuit layer 140 is formed through a semi-additive process (SAP), a modified semi-additive process (MSAP) or a subtractive process.

According to an embodiment, the second circuit layer 150 is formed on the outer side of the insulating material layer 130. When the insulating material layer 130 is formed of RCC, the second circuit layer 150 is formed by patterning the copper foil 135 of the RCC (refer to FIGS. 7 and 8). The second circuit layer 150, like the first circuit layer 140, is also formed through a semi-additive process (SAP), a modified semi-additive process (MSAP) or a subtractive process. Further, vias 160, which penetrate the base plate 110 and the insulating material layer 130 and connect the first circuit layer 140 and the second circuit layer 150, are further formed. Here, the first circuit layer 140, the second circuit layer 150 and the vias 160 are simultaneously formed through a semi-additive process (SAP), a modified semi-additive process (MSAP) or a subtractive process, thus simplifying a manufacturing process.

Meanwhile, as shown in FIG. 3, the electronic component-embedded printed circuit board 200 according to this embodiment further includes a buildup layer 170. The buildup layer is formed on one side of the base plate 110 or the outer side of the insulating material layer 130. Here, the buildup layer 170 can be completed by forming an additional insulating material layer, forming viaholes in the insulating material layer using a YAG laser or a CO₂ laser and then forming a circuit layer including vias through a semi-additive process (SAP) or a modified semi-additive process (MSAP). Meanwhile, in FIG. 3, the buildup layers 170 are formed on one side of the base plate 110 and the outer side of the insulating material layer 130, respectively, and each of the buildup layers 170 has a two layer structure. However, the buildup layers 170 do not need to be formed on the two sides thereof and to have a two layer structure. Although the buildup layer 170 is formed on any one side thereof or has a two or more layer structure, it is included in the scope of the present invention.

According to an embodiment, a solder resist layer 210 is formed on the outermost of the printed circuit board 100 or 200. The solder resist layer 210 is made of a heat-resistant coating material, and serves to protect an outermost circuit layer such that solder is not applied on the outermost circuit layer at the time of soldering. Further, in order to electrically connect the printed circuit board with an external circuit, openings are formed in the solder resist layer 210 to expose pads.

FIGS. 13 and 14 are sectional views showing electronic component-embedded printed circuit boards according to another embodiment of the invention.

As shown in FIGS. 13 and 14, the structure of a base plate 110 of an electronic component-embedded printed circuit board 300 or 400, according to this embodiment, greatly differs from the electronic component-embedded printed circuit board 100 or 200 according to the above-mentioned embodiment. Therefore, the description of the electronic component-embedded printed circuit board 300 or 400 duplicating with the above-mentioned electronic component-embedded printed circuit board 100 or 200 will be omitted, and the base plate 110 will be mainly described.

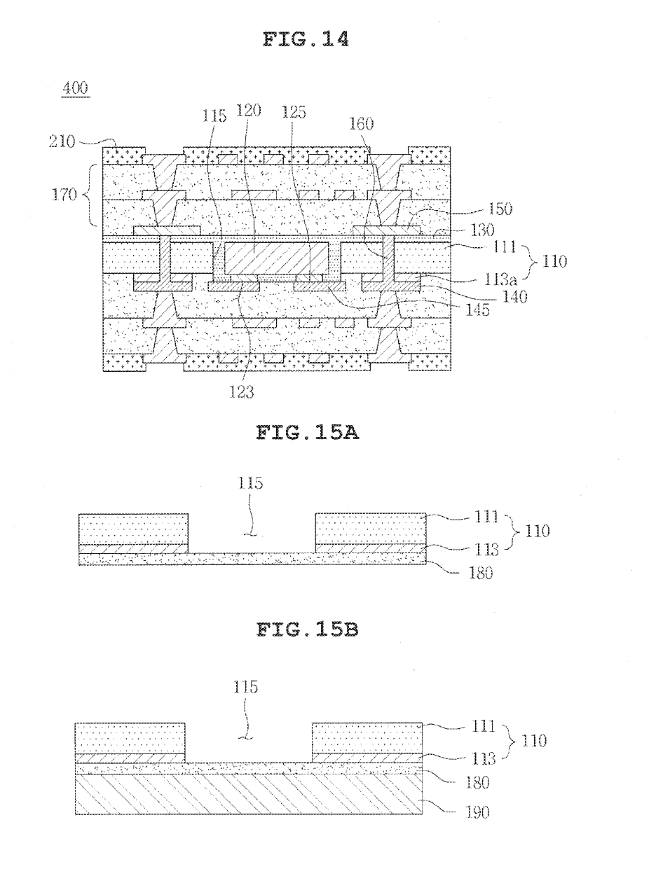

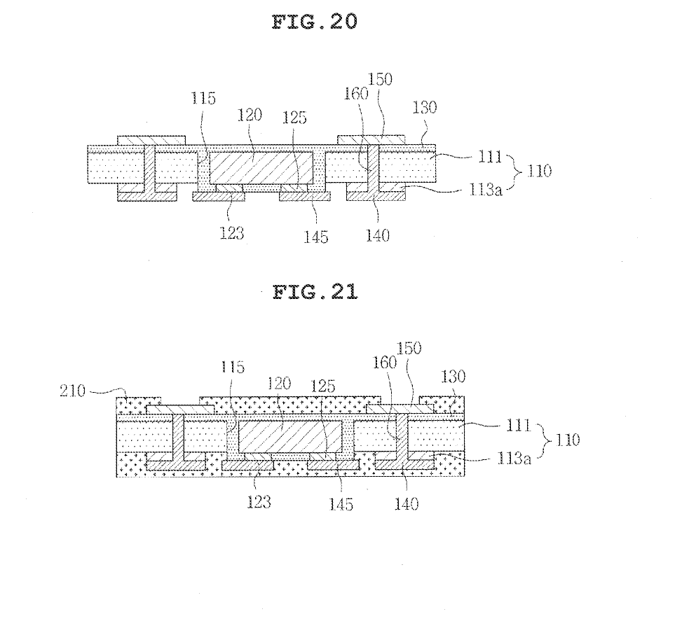

According to an embodiment, the base plate 110 is an insulating plate 111 (refer to FIG. 15) coated with copper foil 113 on one side thereof, and is formed by removing copper foil from a copper clad laminate (CCL) through an etching process or is formed of RCC. Here, the copper foil 113 of the base plate 110 is patterned such that it corresponds to a first circuit layer 140 (refer to FIG. 20). For example, the copper foil 113 of the base plate 110 is patterned by selectively etching the copper foil 113 together with the first circuit layer 140, when the first circuit layer 140 is formed through a subtractive process. In this case, the patterned copper foil 113a plays the same role as the first circuit layer 140 substantially.

According to an embodiment, the electronic component-embedded printed circuit board 300 or 400, according to this embodiment, is advantageous in that it does not warp because the base plate 110 is coated with the copper foil 113.

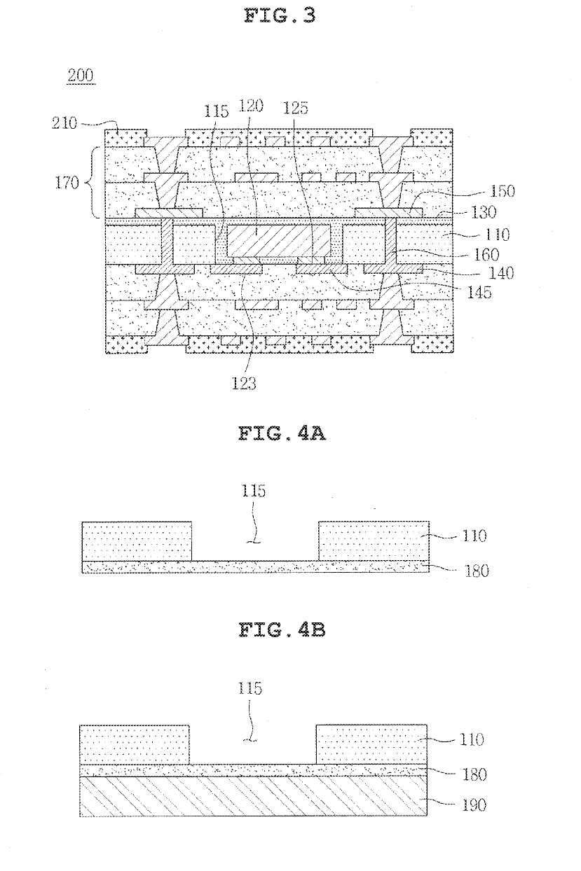

FIGS. 4A, 4B, 5A, 5B, 6A, 6B to 10 are sectional views sequentially showing a method of manufacturing an electronic component-embedded printed circuit board according to an embodiment of the invention.

As shown in FIGS. 4A, 413, 5A, 5B, 6A, 6B to 10, a method of manufacturing an electronic component-embedded printed circuit board according to an embodiment of the invention includes the steps of (A) providing a base plate 110, which has a cavity 115 formed in the thickness direction thereof and to one side of which tape 180 is adhered, (B) disposing an electronic component 120 in the cavity 115, such that the active surface 123 of the electronic component 120 is flush with one side of the base plate 110, (C) forming an insulating material layer 130 on the other side of the base plate 100 to bury the electronic component 120, and (D) removing the tape 180 from the one side of the base plate 110 and then forming a first circuit layer 140 including connection patterns 145 coming into contact with connecting terminals 125 of the electronic component 120 on the one side of the base plate 110. Further, the method of manufacturing an electronic component-embedded printed circuit board, according to this embodiment, further includes the step of forming a buildup layer 170 on one side of the base plate 110 or the outer side of the insulating material layer 130.

First, as shown in 4A to 4B, a base plate 110, which has a cavity 115 formed in the thickness direction thereof and to one side of which tape 180 is adhered, is provided. Here, the base plate 110 is made, for example, of an insulating material generally used to manufacture printed circuit boards. For example, the base plate 110 is formed using an unclad CCL or an epoxy resin.

Meanwhile, the tape 180, which is a temporary member serving to fix an electronic component 120 before the electronic component 120 is buried in the base plate 110 by formation of an insulating material layer 130, is made of an adhesive which does not remain on the base plate 110 or the electronic component 120 even after the tape 180 is removed. More preferably, the tape 180 is made, for example, of an adhesive having excellent heat resistance because heat is applied during a subsequent process of forming the insulating material layer 130. Specifically, polyimide (PI) tape, thermofoaming tape or UV tape is used as the tape 180. Further, as shown in FIGS. 4B, 5B and 6B, since the tape 180 must have a bearing force of predetermined strength or more in order to support the electronic component 120, the tape 180 is provided on one side thereof with a supporting plate 190 made of metal, plastic or ceramic.

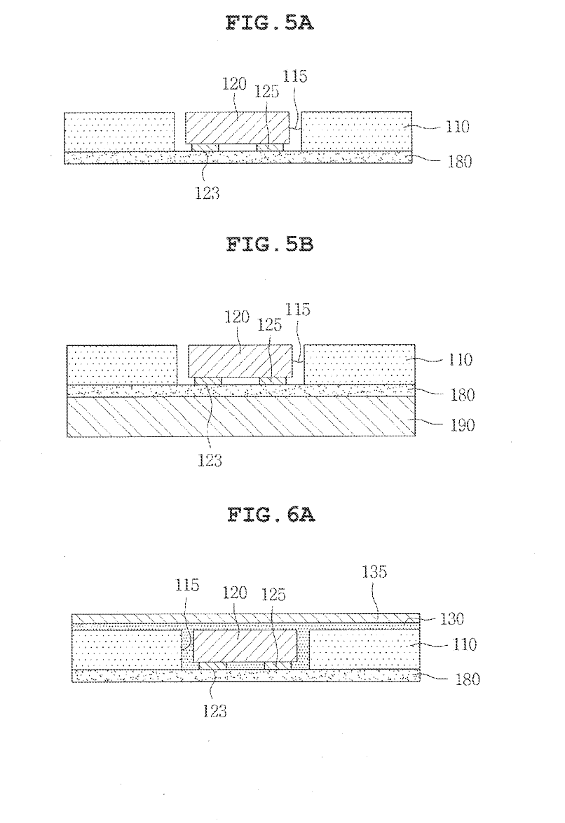

Subsequently, as shown in FIGS. 5A and 5B, an electronic component 120 is disposed in the cavity 115 such that the active surface 123 of the electronic component 120 is flush with one side of the base plate 110. Since the tape 180 has adhesivity, the active surface 123 of the electronic component 120 is adhered to the tape 180, and thus the active surface 123 of the electronic component 120 is flush with the one side of the base plate 110. However, since the active surface 123 of the electronic component 120 is not flush with the one side of the base plate 110, when the tape 180 is warped, as described above, the bearing force of the tape 180 is reinforced by additionally providing the supporting plate 190 on the one side of the tape 180 (refer to FIG. 5B). However, here, the fact that the active surface 123 of the electronic component 120 is flush with the one side of the base plate 110 does not mean that the active surface 123 of the electronic component 120 is completely flush with one side of the base plate 110 mathematically, but means that slight tolerance attributable to the machining error occurring in a manufacturing process may be allowed.

According to an embodiment, the active surface 123 of the electronic component 120 means an outermost surface provided with the connecting terminals 125. Specifically, as shown in FIG. 11, when the connecting terminals 125 are formed to protrude, the active surface of the electronic component 120 is an exposed surface of the connecting terminals 125. In this embodiment, the active surface 123 of the electronic component 120 is explained with reference to the electronic component 120 shown in FIG. 11, but is not limited thereto. As shown in FIG. 12, when the connecting terminals 125 are buried in a passivation layer 127, the active surface of the electronic component 120 is an exposed surface of the passivation layer 127.

Subsequently, as shown in FIGS. 6A and 6B, an insulating material layer 130 is formed on the other side of the base plate 100 to bury the electronic component 120. Here, the insulating material layer 130 is made, for example of an insulating material generally used to manufacture printed circuit boards, for example, RCC or prepreg. When the insulating material layer 130 is formed of RCC, the copper foil 135 of RCC is patterned into a second circuit layer 150 in a subsequent process.

Subsequently, as shown in FIGS. 7 to 9, the tape 180 is removed from one side of the base plate 110, and then a first circuit layer 140 including connection patter is 145 coming into contact with connecting terminals 125 of the electronic component 120 is formed on the one side of the base plate 110. In this process, since the active surface 123 of the electronic component 120 is exposed when the tape 180 is removed, the first circuit layer 140 including the connection patterns 145 are formed without forming additional via holes, and thus the first circuit layer 140 is directly connected with the connecting terminals 125 of the electronic component 120 through the connection patterns 145. Meanwhile, in this process, a second circuit layer 150 is formed on the outer side of the insulating material layer 130. In this case, when the insulating material layer 130 is formed of RCC in the previous process, the second circuit layer 150 is formed by patterning the copper foil 135 of the RCC. In this process, vias 160, which penetrate the base plate 110 and the insulating material layer 130 and connect the first circuit layer 140 and the second circuit layer 150, are further formed, Here, the first circuit layer 140, the second circuit layer 150 and the vias 160 are formed through a semi-additive process (SAP), a modified semi-additive process (MSAP) or a subtractive process.

Subsequently, as shown in FIG. 10, a buildup layer 170 is formed on one side of the base plate 110 or the outer side of the insulating material layer 130. Here, the buildup layer 170 is completed by forming an additional insulating material layer, forming via holes in the insulating material layer using a YAG laser or a CO₂ laser and then forming a circuit layer including vias through a semi-additive process (SAP) or a modified semi-additive process (MSAP). Meanwhile, in FIG. 10, the buildup layers 170 are formed on one side of the base plate 110 and the outer side of the insulating material layer 130, respectively, and each of the buildup layers 170 has a two layer structure. However, the buildup layers 170 do not need to be formed on the two sides thereof and to have a two layer structure. Although the buildup layer 170 is formed on any one side thereof or has a two or more layer structure, it is included in the scope of the present invention.

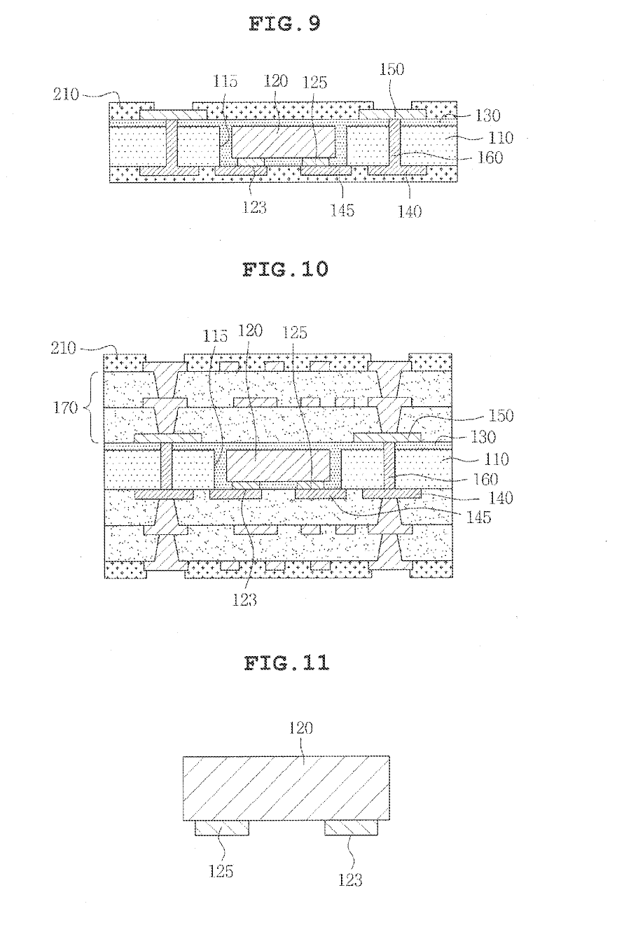

Further, as shown in FIGS. 9 and 10, a solder resist layer 210 is formed on the outermost of the printed circuit board according to this embodiment. The solder resist layer 210 is made of a heat-resistant coating material, and serves to protect an outermost circuit layer such that solder is not applied on the outermost circuit layer at the time of soldering. Further, in order to electrically connect the printed circuit board with an external circuit, openings are formed in the solder resist layer 210 to expose pads.

FIGS. 15A, 15B, 16A, 16B, 17A, 17B to 22 are sectional views sequentially showing a method of manufacturing an electronic component-embedded printed circuit board according to another embodiment of the invention.

As shown in FIGS. 15A, 15B, 16A, 16B, 17A, 17B to 22, a method of manufacturing an electronic component-embedded printed circuit board according to this embodiment greatly differs from the method of manufacturing an electronic component-embedded printed circuit board according to the above-mentioned embodiment in the structure of a base plate 110. Therefore, the base plate 110 will be mainly described.

First, as shown in 15A to 15B, a base plate 110, which has a cavity 115 formed in the thickness direction thereof and to one side of which tape 180 is adhered, is provided. Here, the base plate 110 is an insulating plate 111 coated. with copper foil 113 on one side thereof, and is formed, for example, by removing copper foil from a copper clad laminate (CCL) through an etching process or is formed, for example, of RCC.

As shown in FIGS. 15B, 16B and 17B, since the tape 180 must have a bearing force of predetermined strength or more in order to support an electronic component 120, the tape 180 is provided on one side thereof with a supporting plate 190 made of metal, plastic or ceramic.

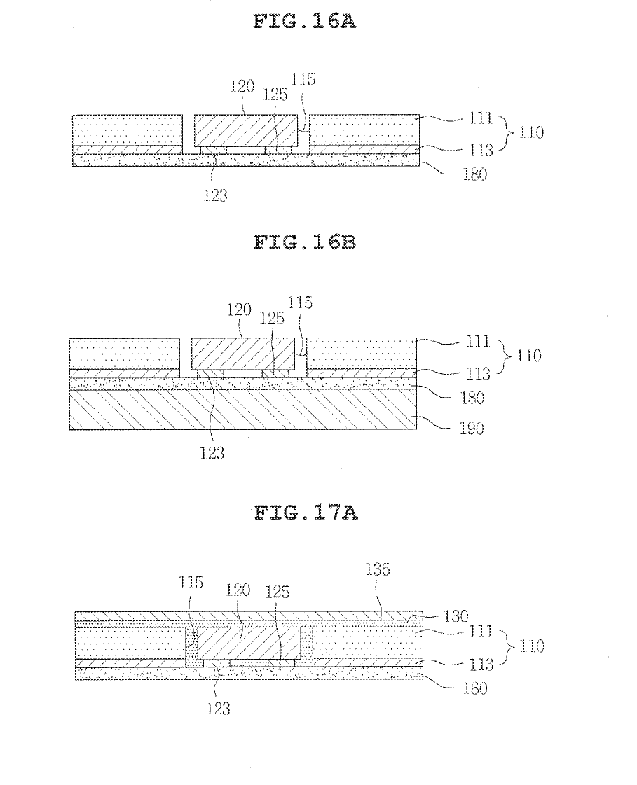

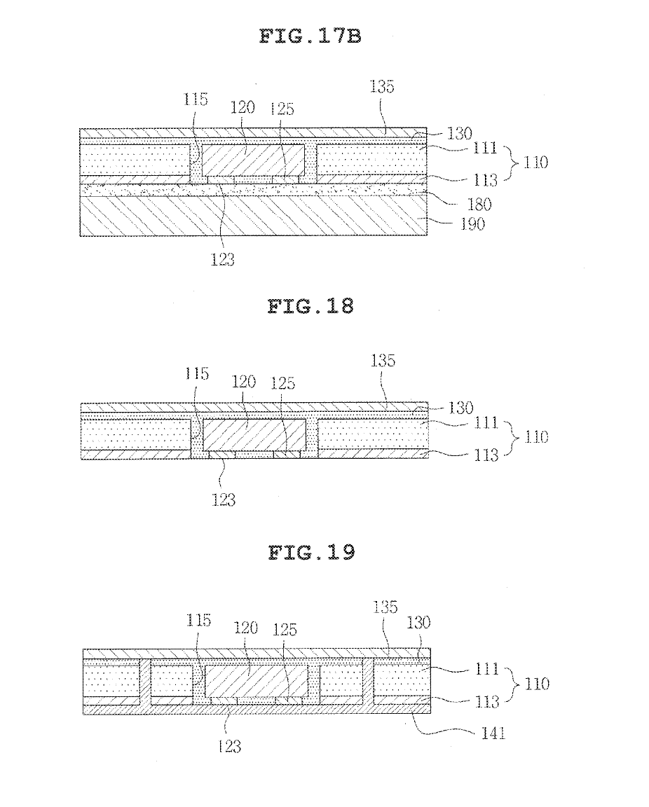

Subsequently, as shown in FIGS. 16A and 16B, an electronic component 120 is disposed in the cavity 115, such that the active, surface 123 of the electronic component 120 is flush with one side of the base plate 110. Since the tape 180 has adhesivity, the active surface 123 of the electronic component 120 is adhered to the tape 180, and thus the active surface 123 of the electronic component 120 is flush with the one side of the base plate 110. However, since the active surface 123 of the electronic component 120 is not flush with the one side of the base plate 110, when the tape 180 is warped, as described above, the bearing force of the tape 180 is reinforced by additionally providing the supporting plate 190 on the one side of the tape 180 (refer to FIG. 16B).

As shown in FIGS, 17A and 17B, an insulating material layer 130 is formed on the other side of the base plate 100 to bury the electronic component 120. Here, the insulating material layer 130 is formed, for example, of RCC. In this case, the copper foil 135 of RCC is patterned into a second circuit layer 150 in a subsequent process.

As shown in FIGS. 18 to 21, the tape 180 is removed from one side of the base plate 110, and then a first circuit layer 140 including connection patterns 145 coming into contact with connecting terminals 125 of the electronic component 120 is formed on the one side of the base plate 110. In this process, since the active surface 123 of the electronic component 120 is exposed when the tape 180 is removed, the first circuit layer 140 including the connection patterns 145 can be formed without forming additional via holes, and thus the first circuit layer 140 is directly connected with the connecting, terminals 125 of the electronic component 120 through the connection patterns 145. Specifically, the first circuit layer 140 is formed by forming a plating layer 141 on the copper foil 113 of the base plate 110 (refer to FIG. 19) and then patterning the plating layer 141 together with the copper foil 113 of the base plate 110 (refer to FIG. 20). Here, the patterned copper foil 113a plays the same role as the first circuit layer 140 substantially. Meanwhile, in this process, a second circuit layer 150 is formed on the outer side of the insulating material layer 130, and vias 160, which penetrate the base plate 110 and the insulating material layer 130 and connect the first circuit layer 140 and the second circuit layer 150, are formed.

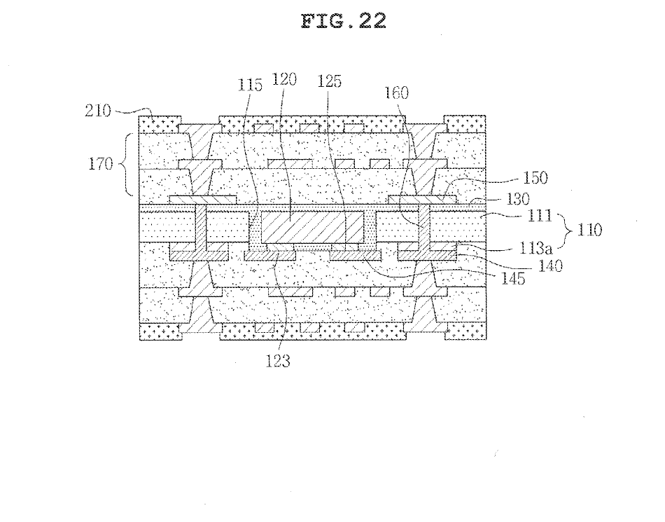

As shown in FIG. 22, a buildup layer 170 is formed on one side of the base plate 110 or the outer side of the insulating material layer 130.

Further, as shown in FIGS. 21 and 22, a solder resist layer 210 is formed on the outermost of the printed circuit board according to this embodiment.

As described above, according to embodiments of the invention, since the active surface of an electronic component is disposed such that it is flush with one side of a base plate, additional via holes do not need to be formed, so that a laser process requiring high cost can be omitted, thereby simplifying the manufacturing process of a printed circuit board and reducing the manufacturing cost thereof.

Further, according, to the present invention, since the connecting terminals of an electronic component are directly connected with the connection patterns of a first circuit layer without vias, the flexibility of circuit design can be improved.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or nonelectrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value, When such a range is expressed, it is to he understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A method of manufacturing an electronic component-embedded printed circuit board, comprising:
providing a base plate which has a cavity formed in a thickness direction thereof and to one side of which tape is adhered;
disposing an electronic component in the cavity such that an active surface of the electronic component is flush with one side of the base plate;
forming an insulating material layer on the other side of the base plate to bury the electronic component; and
removing the tape from the one side of the base plate and then forming a first circuit layer including connection patterns coming into contact with connecting terminals of the electronic component on the one side of the base plate.

2. The method of manufacturing an electronic component-embedded printed circuit board according to claim 1, wherein, in the forming of the first circuit layer, a second circuit layer is formed on an outer side of the insulating material layer.

3. The method of manufacturing an electronic component-embedded printed circuit board according to claim 2, wherein vias penetrating the base plate and the insulating material layer are formed such that the first circuit layer is connected with the second circuit layer.

4. The method of manufacturing an electronic component-embedded printed circuit board according to claim 1, further comprising:
forming a buildup layer on one side of the base plate or an outer side of the insulating material layer after the forming of the first circuit layer.

5. The method of manufacturing an electronic component-embedded printed circuit board according to claim 1, wherein, in the disposing of the electronic component, the active surface of the electronic component is an exposed surface of the connecting terminals of the electronic component.

6. The method of manufacturing an electronic component-embedded printed circuit board according to claim 1, wherein, in the disposing of the electronic component, the active surface of the electronic component is an exposed surface of a passivation layer, and the connecting terminals of the electronic component are buried in the passivation layer.

7. The method of manufacturing an electronic component-embedded printed circuit board according to claim 1, wherein, in the providing of the base plate, the tape is polyimide (PI) tape, thermofoaming tape or UV tape.

8. The method of manufacturing an electronic component-embedded printed circuit board according to claim 1, wherein, in the providing of the base plate, the tape is provided with a supporting plate on one side thereof.

9. The method of manufacturing an electronic component-embedded printed circuit board according to claim 1, wherein, in the providing of the base plate, the base plate is formed of an unclad CCL or an epoxy resin.

10. The method of manufacturing an electronic component-embedded printed circuit board according to claim 1, wherein, in the providing of the base plate, the base plate is an insulating plate coated with copper foil on one side thereof, and
wherein, in the forming of the first circuit layer, the first circuit layer is formed by forming a plating layer on the copper foil of the base plate and then patterning the plating layer together with the copper foil of the base plate.

11. The method of manufacturing an electronic component-embedded printed circuit board according to claim 1, wherein, in the forming of the insulating material layer, the insulation material layer is formed of resin coated copper foil or prepreg.
